(19) United States
(12) Patent Application Publication
(10) Pub. No.: US 2026/0223681 A1
(43) Pub. Date: Jul. 30, 2026

(54) SEMICONDUCTOR DEVICE

(71) Applicant: Mitsubishi Electric Corporation, Tokyo (JP)

(72) Inventors: Koji TANAKA, Tokyo (JP); Takashi FUJIMOTO, Tokyo (JP); Reona FURUKAWA, Tokyo (JP); Kazuya KONISHI, Tokyo (JP)

(73) Assignee: Mitsubishi Electric Corporation, Tokyo (JP)

(21) Appl. No.: 19/294,381

(22) Filed: Aug. 8, 2025

(30) Foreign Application Priority Data
Jan. 24, 2025 (JP) 2025-010382

(51) Int. Cl. H01L 23/00; H01L 23/34; H10D 12/00; H10D 64/00; H10D 64/23

(52) U.S. Cl. CPC H10W 42/121; H10D 12/481; H10D 64/117; H10D 64/232; H10W 40/00

(57) ABSTRACT

In the active trench, a first lower electrode is formed on a lower side, and a first upper electrode is formed on an upper side with respect to the first intermediate insulating film. In the dummy trench, a second lower electrode is formed on a lower side, and a second upper electrode is formed on an upper side with respect to the second intermediate insulating film. A gate wiring is connected to the first lower electrode, the first upper electrode and the second lower electrode. A metal film is embedded in an opening formed in a stripe shape in the interlayer insulating film. An emitter electrode is connected to the second upper electrode and the base layer and the source layer via the metal film embedded in the opening. The metal film has a higher young's modulus than that of each of the emitter electrode and the semiconductor substrate.

### BACKGROUND OF THE INVENTION

### Field

The present disclosure relates to a semiconductor device.

### Background

There has been developed a semiconductor device having a split dummy active (hereinafter, referred to as an SDA) structure in which the inside of a dummy trench is divided into an upper part and a lower part by an intermediate insulating film, a lower electrode on a lower side with respect to the intermediate insulating film is set at a gate potential, and an upper electrode on an upper side with respect to the intermediate insulating film is set at an emitter potential. In the case of the SDA structure, a gate current flows only through the lower electrode, so that heat is generated only in a trench lower region to cause a temperature difference from the upper electrode, making it easy to cause thermal stress. Therefore, after the electric conduction in a chip test or the like, a chip is warped, and a failure occurs during die bonding. As an example, there has been proposed that in the structure in which the inside of the trench is divided into the upper part and the lower part by the intermediate insulating film, the trench is arranged to have a cross shape in plan view, so that the warping can be reduced (for example, see Patent Literature 1).

### CITATION LIST

### Patent Literature

Patent Literature 1: WO 2022/201903

### SUMMARY

### Technical Problem

However, it is necessary to increase gate wirings to arrange the trench in a cross shape, which reduces the effective area.

The present disclosure has been made in order to solve the problem described above, and an object thereof is to obtain a semiconductor device that can reduce the warping of a chip without reducing an effective area.

### Solution to Problem

A semiconductor device according to the present disclosure includes: a semiconductor substrate including a drift layer of a first conductivity type, a base layer of a second conductivity type formed on the drift layer, and a source layer of a first conductivity type formed on a part of the base layer; a first intermediate insulating film dividing an inside of an active trench into an upper part and a lower part, the active trench formed from an upper surface of the semiconductor substrate to the drift layer through the base layer and the source layer; a first lower electrode formed on a lower side with respect to the first intermediate insulating film in the active trench; a first upper electrode formed on an upper side with respect to the first intermediate insulating film in the active trench; a second intermediate insulating film dividing an inside of a dummy trench into an upper part and a lower part, the dummy trench formed from the upper surface of the semiconductor substrate to the drift layer through the base layer; a second lower electrode formed on a lower side with respect to the second intermediate insulating film in the dummy trench; a second upper electrode formed on an upper side with respect to the second intermediate insulating film in the dummy trench; an interlayer insulating film formed on the semiconductor substrate to cover the active trench and the dummy trench; a gate wiring connected to the first lower electrode, the first upper electrode and the second lower electrode; a metal film embedded in an opening formed in a stripe shape along the active trench and the dummy trench in plan view in the interlayer insulating film; and an emitter electrode formed on the interlayer insulating film, not entering the opening, connected to the second upper electrode, and connected to the base layer and the source layer via the metal film embedded in the opening, wherein the metal film has a higher young's modulus than that of each of the emitter electrode and the semiconductor substrate.

### Advantageous Effects of Invention

In the present disclosure, the metal film having a high young's modulus is embedded in the stripe-shaped opening, which makes it difficult to deform the semiconductor substrate even when the stress is applied. This makes it possible to reduce the warping in the upward concave direction that is generated in the SDA structure. In addition, it is unnecessary to increase the number of gate wirings as in the conventional technique in which the trench is arranged in a cross shape. This can reduce the warping of a chip without reducing an effective area.

### BRIEF DESCRIPTION OF DRAWINGS

FIG. 1 is a plan view illustrating a semiconductor device according to a first embodiment.

FIG. 2 is a cross-sectional view illustrating the main cell part of the semiconductor device according to the first embodiment.

FIG. 3 is an enlarged plan view of a region A enclosed by a broken line in the main cell part in FIG. 1.

FIG. 4 is a cross-sectional view of an end portion of the active trench along the trench longitudinal direction.

FIG. 5 is a cross-sectional view of an end portion of the dummy trench along the trench longitudinal direction.

FIG. 6 is a cross-sectional view taken along line I-II in FIG. 5.

FIG. 7 is an enlarged plan view of the gate pad in FIG. 1.

FIG. 8 is a cross-sectional view taken along line I-II in FIG. 7.

FIG. 9 is a cross-sectional view illustrating the temperature sense diode in FIG. 1.

FIG. 10 is a diagram illustrating an assembly failure rate of each of the first embodiment and a comparative example.

FIG. 11 is a cross-sectional view illustrating a modified example of the semiconductor device according to the first embodiment.

FIG. 12 is a cross-sectional view illustrating another modified example of the semiconductor device according to the first embodiment.

FIG. 13 is a cross-sectional view illustrating another modified example of the semiconductor device according to the first embodiment.

FIG. 14 is a cross-sectional view illustrating a semiconductor device according to a second embodiment.

FIG. 15 is a cross-sectional view illustrating a modified example of the semiconductor device according to the second embodiment.

FIG. 16 is a cross-sectional view illustrating a semiconductor device according to a third embodiment.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

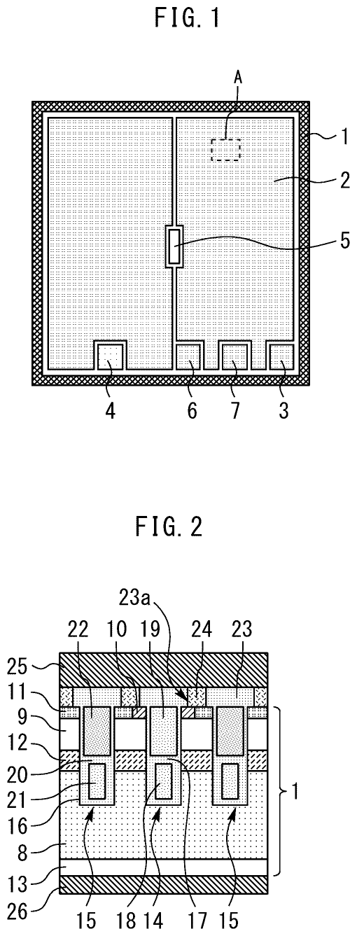

FIG. 1 is a plan view illustrating a semiconductor device according to a first embodiment. A semiconductor substrate 1 is made of silicon, and includes a main cell part 2 and a current sense part 3. An IGBT or RC-IGBT is formed in the main cell part 2. The same structure as the main cell part 2 is formed in the current sense part 3. A gate pad 4, a temperature sense diode 5, and temperature sense diode pads 6 and 7 are formed on the semiconductor substrate 1.

FIG. 2 is a cross-sectional view illustrating the main cell part of the semiconductor device according to the first embodiment. In the semiconductor substrate 1, a p-type base layer 9 is formed on a drift layer 8. An n⁺-type source layer 10 and a p⁺-type contact layer 11 are formed on a part of the base layer 9. An n⁺-type charge storage layer 12 is formed between the drift layer 8 and the base layer 9. A p-type collector layer 13 is formed beneath the drift layer 8.

An active trench 14 is formed from the upper surface of the semiconductor substrate 1 to the drift layer 8 through the source layer 10, the base layer 9, and the charge storage layer 12. A dummy trench 15 is formed from the upper surface of the semiconductor substrate 1 to the drift layer 8 through the contact layer 11, the base layer 9, and the charge storage layer 12. The depth of the active trench 14 is equal to the depth of the dummy trench 15. The inner surface of each of the active trench 14 and the dummy trench 15 is covered by a gate insulating film 16.

The inside of the active trench 14 is divided into an upper part and a lower part by a first intermediate insulating film 17. A first lower electrode 18 is formed on the lower side with respect to the first intermediate insulating film 17 in the active trench 14. A first upper electrode 19 is formed on the upper side with respect to the first intermediate insulating film 17 in the active trench 14.

The inside of the dummy trench 15 is divided into an upper part and a lower part by a second intermediate insulating film 20. A second lower electrode 21 is formed on the lower side with respect to the second intermediate insulating film 20 in the dummy trench 15. A second upper electrode 22 is formed on the upper side with respect to the second intermediate insulating film 20 in the dummy trench 15.

An interlayer insulating film 23 is formed on the semiconductor substrate 1 to cover the active trench 14 and the dummy trench 15. A metal film 24 is embedded in an opening 23a formed in the interlayer insulating film 23. The emitter electrode 25 is formed on the interlayer insulating film 23. The emitter electrode 25 does not enter the opening 23a, and is connected to the base layer 9 and the source layer 10 via the metal film 24 embedded in the opening 23a. A collector electrode 26 is formed in the lower surface of the semiconductor substrate 1, and is connected to the collector layer 13.

The emitter electrode 25 is an Al film, a laminated film of Al and Ni, or a Cu film. These materials are easily available at low cost, and are resistant to a process after the electrode is formed and are resistant during assembly. For example, in the wire bonding during the assembly, wires are ultrasonically bonded while being subjected to vibration generated by physically applying a load. Therefore, the thickness and hardness that can be resistant to the ultrasonic bonding are required for the upper electrode. However, when the upper electrode is formed of only the thick metal film 24, the chip is warped in an upward concave direction during a wafer process. Accordingly, the emitter electrode 25 made of the above-described material is formed as the upper electrode.

The metal film 24 is made of tungsten, but is not limited to this, and may be made of tantalum, titanium, titanium nitride, or the like. The metal film 24 may be a laminated film of a plurality of metal films. The metal film 24 made of these materials has a higher young's modulus than that of each of the emitter electrode 25 made of the above-described material and the semiconductor substrate 1 made of silicon.

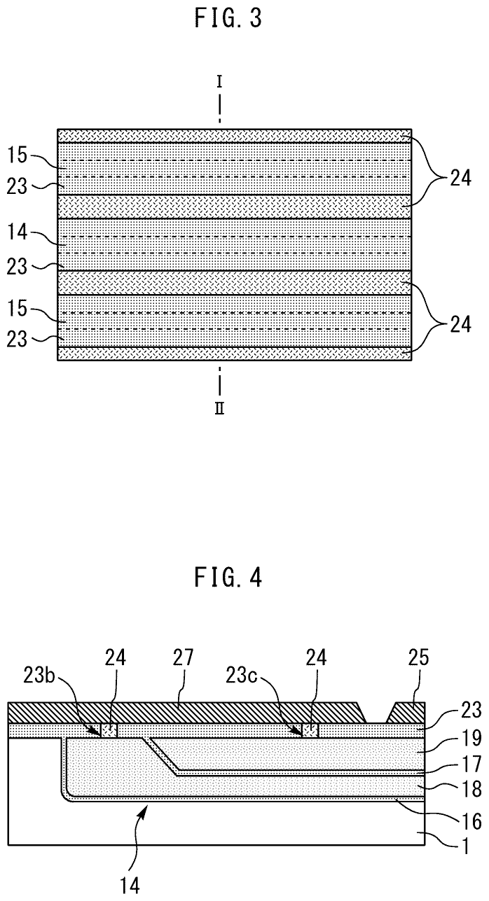

FIG. 3 is an enlarged plan view of a region A enclosed by a broken line in the main cell part in FIG. 1. FIG. 2 corresponds to a cross-sectional view taken along line I-II in FIG. 3. The emitter electrode 25 is not illustrated. The stripe-shaped active trench 14 and dummy trench 15 are arranged in parallel to each other in plan view, and the interlayer insulating film 23 is formed on the active trench 14 and the dummy trench 15. The opening 23a is formed in a stripe shape along the active trench 14 and the dummy trench 15 in plan view in the interlayer insulating film 23. The metal film 24 that has a high young's modulus and is embedded in the opening 23a extends in the entire trench longitudinal direction along a direction in which the active trench 14 and the dummy trench 15 extend in plan view. This makes it possible to reduce the warping of the chip in the trench longitudinal direction.

FIG. 4 is a cross-sectional view of an end portion of the active trench along the trench longitudinal direction. A gate wiring 27 is connected to the first lower electrode 18 via the metal film 24 embedded in a contact hole 23b in the interlayer insulating film 23, and is also connected to the first upper electrode 19 via the metal film 24 embedded in a contact hole 23c in the interlayer insulating film 23.

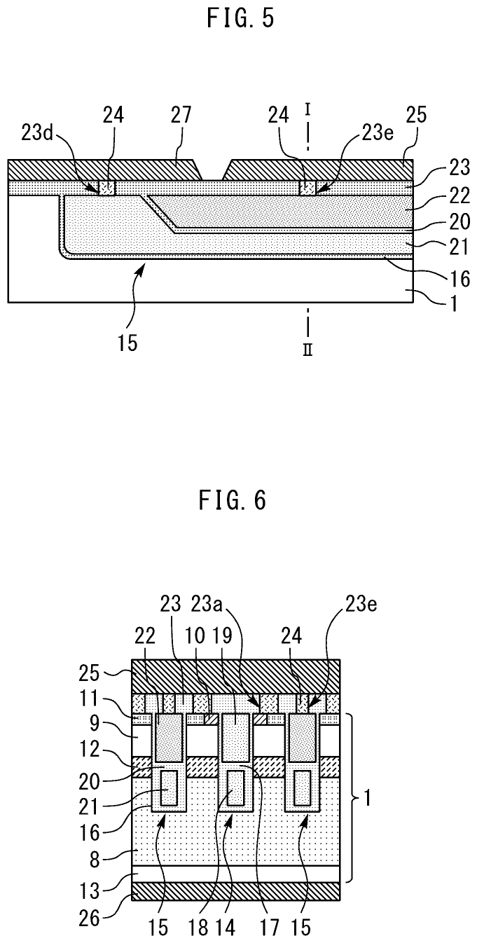

FIG. 5 is a cross-sectional view of an end portion of the dummy trench along the trench longitudinal direction. FIG. 6 is a cross-sectional view taken along line I-II in FIG. 5. A gate wiring 27 is connected to the second lower electrode 21 via the metal film 24 embedded in a contact hole 23d in the interlayer insulating film 23. A contact hole 23e that passes through the interlayer insulating film 23 and reaches the second upper electrode 22 is formed. The emitter electrode 25 is connected to the second upper electrode 22 via the metal film 24 embedded in the contact hole 23e. Note that the contact hole 23e is formed in each of the end portion of the main cell region in the trench longitudinal direction and the termination region of the chip outer periphery, but may be formed only in the termination region. Since the potential of the second lower electrode 21 of the dummy trench 15 is the gate potential, and the potential of the second upper electrode 22 is the emitter potential, the dummy trench 15 has the SDA structure.

The application taking into account motor insulation, such as motion control application has a dv/dt limitation. In contrast, a capacitance Cgc between the gate and the collector is increased by adopting the SDA structure. This can reduce a ratio Cge/Cgc between a capacitance Cge between the gate and the emitter and the capacitance Cgc, so that dv/dt at the time of turn-on can be reduced and di/dt can be increased. Therefore, even when the user side has a dv/dt limitation, loss Eon at the time of turn-on can be reduced.

In a case of a normal single-step trench, the dummy trench includes no gate potential electrode and only an emitter potential electrode. In a case where the single-step trench is changed to the SDA structure, the volume of the gate electrode is increased, so that a charge amount Qg for driving the gate increases. When the charge amount Qg increases, there is a possibility that the user side requires to design a gate driver having larger output than ever, which may cause opportunity loss. Then, in the dummy trench 15 having the SDA structure, the gate insulating film 16 of the second lower electrode 21 is set to be thicker than the gate insulating film 16 of the second upper electrode 22. This can reduce the volume of the gate electrode and achieve the charge amount Qg equivalent to that of the conventional single-step trench.

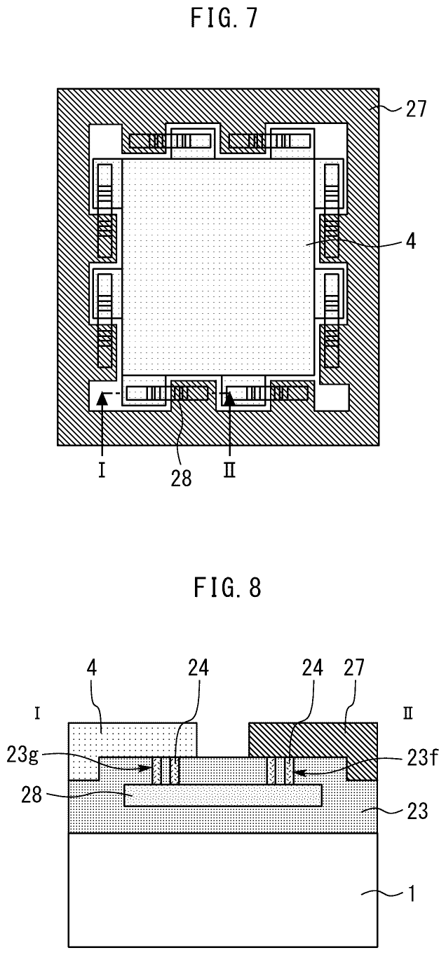

FIG. 7 is an enlarged plan view of the gate pad in FIG. 1. FIG. 8 is a cross-sectional view taken along line I-II in FIG. 7. The gate pad 4 and the gate wiring 27 are formed on the interlayer insulating film 23 so as to be spaced apart from each other. A resistor 28 is formed on the semiconductor substrate 1, and is covered by the interlayer insulating film 23. A contact hole 23f and a contact hole 23g are formed in the interlayer insulating film 23. The gate wiring 27 is connected to one end of the resistor 28 via the metal film 24 embedded in the contact hole 23f. The gate pad 4 is connected to the other end of the resistor 28 via the metal film 24 embedded in the contact hole 23g. Thus, the metal film 24 is also used for a contact of the resistor 28 on the periphery of the gate pad 4.

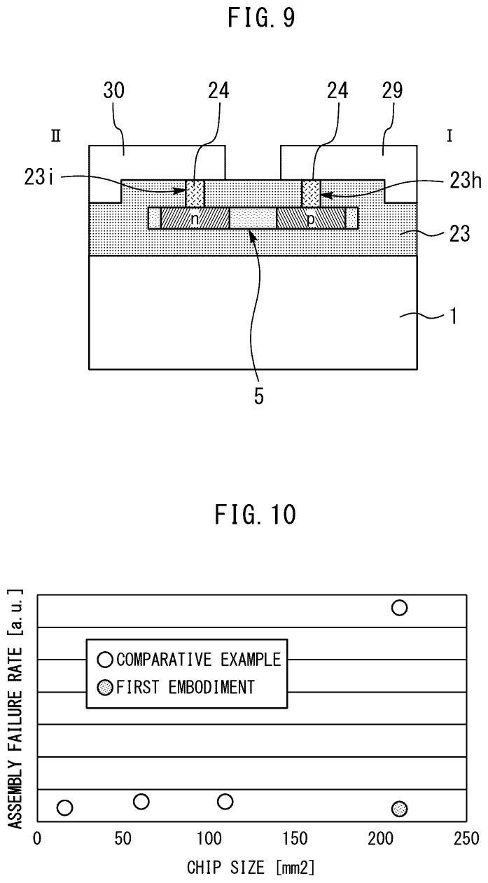

FIG. 9 is a cross-sectional view illustrating the temperature sense diode in FIG. 1. The temperature sense diode 5 is formed on the semiconductor substrate 1, and is covered by the interlayer insulating film 23. An anode electrode 29 and a cathode electrode 30 are formed on the interlayer insulating film 23 so as to be spaced apart from each other. The temperature sense diode 5 is a pn diode made of polysilicon. A contact hole 23h and a contact hole 23i are formed in the interlayer insulating film 23. The anode electrode 29 is connected to one end of the temperature sense diode 5 via the metal film 24 embedded in the contact hole 23h. The cathode electrode 30 is connected to the other end of the temperature sense diode 5 via the metal film 24 embedded in the contact hole 23i. Thus, the metal film 24 is also used for a contact of the temperature sense diode 5.

As described above, in the present embodiment, the metal film 24 having a high young's modulus is embedded in the stripe-shaped opening 23a, which makes it difficult to deform the semiconductor substrate 1 even when the stress is applied. This makes it possible to reduce the warping in the upward concave direction that is generated in the SDA structure. In addition, it is unnecessary to increase the number of gate wirings 27 as in the conventional technique in which the trench is arranged in a cross shape. This can reduce the warping of a chip without reducing an effective area.

The metal film 24 is formed not only in the opening 23a in the main cell part 2 but also in each of the contact holes 23b to 23i. This increases an area occupied by the metal films 24 having a high young's modulus in the chip surface, so that the warping of the semiconductor substrate 1 due to the SDA structure can be further reduced.

In each of the main cell part 2 and the current sense part 3, the active trench 14 and the dummy trench 15 are formed, and the emitter electrode 25 is connected to the base layer 9 and the source layer 10 via the metal film 24 embedded in the opening 23a. Thus, the metal film 24 is also used in the current sense part 3, which increases an area occupied by the metal films 24 having a high young's modulus in the chip surface, so that the warping of the semiconductor substrate 1 due to the SDA structure can be further reduced.

The interlayer insulating film 23 is made of SiO₂ such as TEOS, and BPTEOS, and is formed by CVD. However, a compression stress is generated in the SiO₂ film, and a tensile stress is generated in the Si substrate, so that a warping force in the upward concave direction acts in a case where the interlayer insulating film 23 is made of SiO₂. Then, SiN is used as the interlayer insulating film 23. The SiN has the tensile stress as the internal stress. This causes the compression stress in the semiconductor substrate 1, so that the warping in the upward concave direction that is generated in the SDA structure can be further reduced.

FIG. 10 is a diagram illustrating an assembly failure rate of each of the first embodiment and a comparative example. The larger the size of the semiconductor substrate 1 is, the larger the chip warping is. In particular, when the size of the semiconductor substrate 1 is 110 mm² or more, the assembly failure rate increases in the comparative example. On the other hand, in the present embodiment, the assembly failure rate does not increase even when the size of the semiconductor substrate 1 is 110 mm² or more.

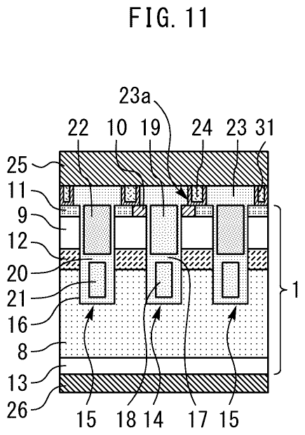

FIG. 11 is a cross-sectional view illustrating a modified example of the semiconductor device according to the first embodiment. The metal film 24 has a higher young's modulus and a lower thermal expansion coefficient than those of silicon. Therefore, when the metal film 24 is directly attached to the semiconductor substrate 1, the differences between the metal film 24 and the semiconductor substrate 1 are large, which may cause separation between the metal film 24 and the semiconductor substrate 1. A barrier metal 31 having a higher thermal expansion coefficient than that of the metal film 24 is formed between the semiconductor substrate 1 and the metal film 24 in the opening 23a. The barrier metal 31 having a high thermal expansion coefficient is thus sandwiched between the semiconductor substrate 1 and the metal film 24, which makes it possible to prevent the separation therebetween.

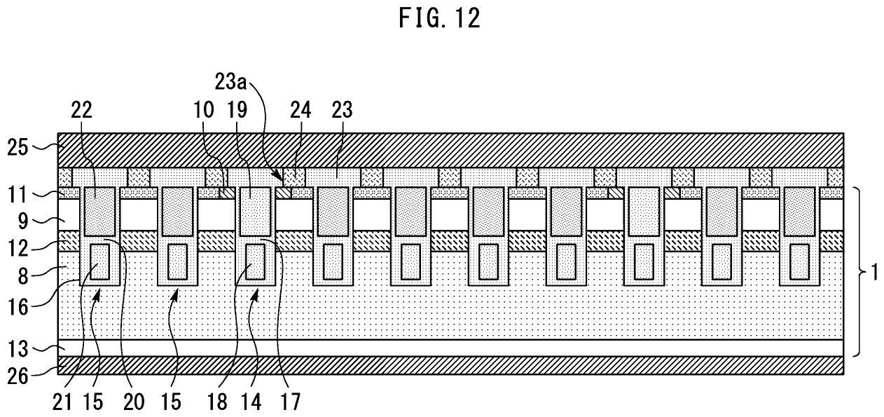

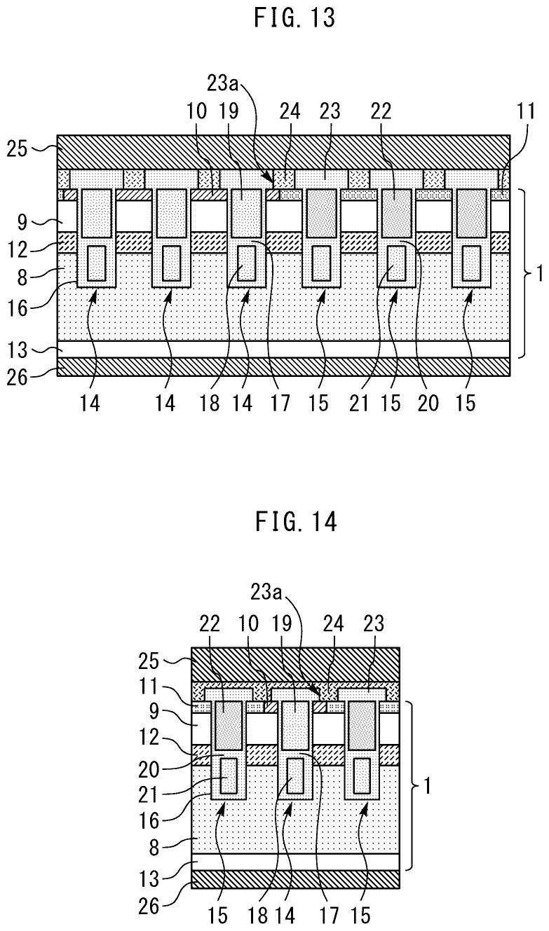

FIGS. 12 and 13 each are a cross-sectional view illustrating another modified example of the semiconductor device according to the first embodiment. In the above-described embodiment, one active trench 14 and one dummy trench 15 are alternately arranged. Without limitation to this configuration, one active trench 14 and four dummy trenches 15 may be alternately arranged as illustrated in FIG. 12, or three active trenches 14 and three dummy trenches 15 may be alternately arranged as illustrated in FIG. 13.

### Second Embodiment

FIG. 14 is a cross-sectional view illustrating a semiconductor device according to a second embodiment. In the present embodiment, a metal film 24 is formed not only in an opening 23a but also on the upper surface of the interlayer insulating film 23. The height of the metal film 24 embedded in the opening 23a and the metal film 24 on the upper surface of the interlayer insulating film 23 is the same as the height from the upper surface of the semiconductor substrate 1. Since the metal film 24 has a higher young's modulus than that of the interlayer insulating film 23, the warping of the chip can be reduced not only in the trench longitudinal direction but also in a direction perpendicular to the trench. As a result, the maximum warping of the entire chip can be further reduced than that in the first embodiment.

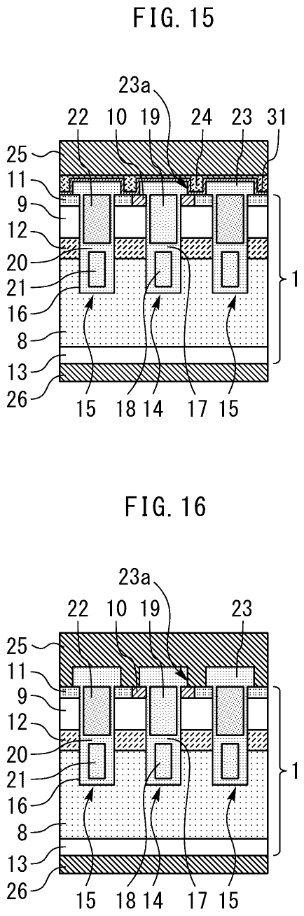

FIG. 15 is a cross-sectional view illustrating a modified example of the semiconductor device according to the second embodiment. A barrier metal 31 having a higher thermal expansion coefficient than that of the metal film 24 is formed between the semiconductor substrate 1 and the interlayer insulating film 23 and between the semiconductor substrate 1 and the metal film 24. The barrier metal 31 having a high thermal expansion coefficient is thus sandwiched between the semiconductor substrate 1 and the interlayer insulating film 23 and between the semiconductor substrate 1 and the metal film 24, which makes it possible to prevent the separation therebetween.

### Third Embodiment

FIG. 16 is a cross-sectional view illustrating a semiconductor device according to a third embodiment. In the present embodiment, an emitter electrode 25 serving as the upper electrode is made of aluminum, and has a tensile stress as the internal stress. On the other hand, a collector electrode 26 serving as the lower electrode is made of nickel vanadium or molybdenum, and has a compression stress as the internal stress. Since a stress in a direction opposite to the internal stress generated in the SDA structure is generated in the collector electrode 26, the warping in the upward concave direction that is generated in the SDA structure can be reduced. Note that, as in the first and second embodiments, metal films 24 having a high young's modulus may be formed in an opening 23a and contact holes 23b to 23i and on the upper surface of an interlayer insulating film 23. This can further reduce the warping of the semiconductor substrate 1 due to the SDA structure.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### (Supplementary Note 1)

A Semiconductor Device Comprising:
a semiconductor substrate including a drift layer of a first conductivity type, a base layer of a second conductivity type formed on the drift layer, and a source layer of a first conductivity type formed on a part of the base layer;
a first intermediate insulating film dividing an inside of an active trench into an upper part and a lower part, the active trench formed from an upper surface of the semiconductor substrate to the drift layer through the base layer and the source layer;
a first lower electrode formed on a lower side with respect to the first intermediate insulating film in the active trench;
a first upper electrode formed on an upper side with respect to the first intermediate insulating film in the active trench;
a second intermediate insulating film dividing an inside of a dummy trench into an upper part and a lower part, the dummy trench formed from the upper surface of the semiconductor substrate to the drift layer through the base layer;
a second lower electrode formed on a lower side with respect to the second intermediate insulating film in the dummy trench;
a second upper electrode formed on an upper side with respect to the second intermediate insulating film in the dummy trench;
an interlayer insulating film formed on the semiconductor substrate to cover the active trench and the dummy trench;
a gate wiring connected to the first lower electrode, the first upper electrode and the second lower electrode;
a metal film embedded in an opening formed in a stripe shape along the active trench and the dummy trench in plan view in the interlayer insulating film; and
an emitter electrode formed on the interlayer insulating film, not entering the opening, connected to the second upper electrode, and connected to the base layer and the source layer via the metal film embedded in the opening,
wherein the metal film has a higher young's modulus than that of each of the emitter electrode and the semiconductor substrate.

### (Supplementary Note 2)

The semiconductor device according to Supplementary Note 1, wherein the metal film is formed on an upper surface of the interlayer insulating film and has a higher young's modulus than that of the interlayer insulating film.

### (Supplementary Note 3)

The semiconductor device according to Supplementary Note 1 or 2, further comprising a barrier metal formed between the semiconductor substrate and the metal film in the opening and having a higher thermal expansion coefficient than that of the metal film.

(Supplementary Note 4)

The semiconductor device according to any one of Supplementary Notes 1 to 3, wherein a first contact hole that passes through the interlayer insulating film and reaches the second upper electrode is formed, and
the emitter electrode is connected to the second upper electrode via the metal film embedded in the first contact hole.

### (Supplementary Note 5)

The semiconductor device according to any one of Supplementary Notes 1 to 4, further comprising
a gate pad formed on the interlayer insulating film, and
a resistor formed on the semiconductor substrate and covered by the interlayer insulating film,
wherein the gate wiring is formed on the interlayer insulating film,
a second contact hole and a third contact hole are formed in the interlayer insulating film,
the gate wiring is connected to one end of the resistor via the metal film embedded in the second contact hole, and
the gate pad is connected to the other end of the resistor via the metal film embedded in the third contact hole.

### (Supplementary Note 6)

The semiconductor device according to any one of Supplementary Notes 1 to 5, further comprising
a temperature sense diode formed on the semiconductor substrate and covered by the interlayer insulating film, and
an anode electrode and a cathode electrode formed on the interlayer insulating film,
wherein the temperature sense diode is a pn diode made of polysilicon,
a fourth contact hole and a fifth contact hole are formed in the interlayer insulating film,
the anode electrode is connected to one end of the temperature sense diode via the metal film embedded in the fourth contact hole, and
the cathode electrode is connected to the other end of the temperature sense diode via the metal film embedded in the fifth contact hole.

### (Supplementary Note 7)

The semiconductor device according to any one of Supplementary Notes 1 to 6, wherein the semiconductor substrate includes a main cell part and a current sense part, and
in each of the main cell part and the current sense part, the active trench and the dummy trench are formed, and the emitter electrode is connected to the base layer and the source layer via the metal film embedded in the opening.

### (Supplementary Note 8)

The semiconductor device according to any one of Supplementary Notes 1 to 7, wherein the metal film is made of tungsten.

### (Supplementary Note 9)

The semiconductor device according to any one of Supplementary Notes 1 to 8, further comprising a lower electrode formed on a lower surface of the semiconductor substrate,
wherein the emitter electrode has a tensile stress as an internal stress, and
the lower electrode has a compression stress as an internal stress.

(Supplementary Note 10)

A semiconductor device comprising:
a semiconductor substrate including a drift layer of a first conductivity type, a base layer of a second conductivity type formed on the drift layer, and a source layer of a first conductivity type formed on a part of the base layer;
a first intermediate insulating film dividing an inside of an active trench into an upper part and a lower part, the active trench formed from an upper surface of the semiconductor substrate to the drift layer through the base layer and the source layer;
a first lower electrode formed on a lower side with respect to the first intermediate insulating film in the active trench;
a first upper electrode formed on an upper side with respect to the first intermediate insulating film in the active trench;
a second intermediate insulating film dividing an inside of a dummy trench into an upper part and a lower part, the dummy trench formed from the upper surface of the semiconductor substrate to the drift layer through the base layer;
a second lower electrode formed on a lower side with respect to the second intermediate insulating film in the dummy trench;
a second upper electrode formed on an upper side with respect to the second intermediate insulating film in the dummy trench;
an interlayer insulating film formed on the semiconductor substrate to cover the active trench and the dummy trench;
a gate wiring connected to the first lower electrode, the first upper electrode and the second lower electrode;
an emitter electrode formed on the interlayer insulating film, connected to the second upper electrode, and connected to the base layer and the source layer via a contact hole formed in the interlayer insulating film; and
a lower electrode formed on a lower surface of the semiconductor substrate,
wherein the emitter electrode has a tensile stress as an internal stress, and
the lower electrode has a compression stress as an internal stress.

### (Supplementary Note 11)

The semiconductor device according to Supplementary Note 10, wherein the emitter electrode is made of aluminum, and
the lower electrode is made of nickel vanadium or molybdenum.

### (Supplementary Note 12)

The semiconductor device according to any one of Supplementary Notes 1 to 11, wherein the semiconductor substrate is made of silicon.

### (Supplementary Note 13)

The semiconductor device according to any one of Supplementary Notes 1 to 12, wherein the interlayer insulating film is made of SiN.

### (Supplementary Note 14)

The semiconductor device according to any one of Supplementary Notes 1 to 13, wherein a size of the semiconductor substrate is 110 mm² or more.

### (Supplementary Note 15)

The semiconductor device according to any one of Supplementary Notes 1 to 15, wherein the semiconductor device is an IGBT or RC-IGBT.

### REFERENCE SIGNS LIST

1 semiconductor substrate ; 2 main cell part; 3 current sense part; 4 gate pad; 5 temperature sense diode; 8 drift layer; 9 base layer; 10 source layer; 14 active trench; 15 dummy trench; 17 first intermediate insulating film; 18 first lower electrode; 19 first upper electrode; 20 second intermediate insulating film; 21 second lower electrode; 22 second upper electrode; 23 interlayer insulating film; 23a opening; 23b~23i contact hole; 24 metal film; 25 emitter electrode; 26 collector electrode (lower electrode); 27 gate wiring; 28 resistor; 29 anode electrode; 30 cathode electrode; 31 barrier metal

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2025-010382, filed on Jan. 24, 2025 including specification, claims, drawings and summary, on which the convention priority of the present application is based, is incorporated herein by reference in its entirety.

1. A semiconductor device comprising:
a semiconductor substrate including a drift layer of a first conductivity type, a base layer of a second conductivity type formed on the drift layer, and a source layer of a first conductivity type formed on a part of the base layer;
a first intermediate insulating film dividing an inside of an active trench into an upper part and a lower part, the active trench formed from an upper surface of the semiconductor substrate to the drift layer through the base layer and the source layer;
a first lower electrode formed on a lower side with respect to the first intermediate insulating film in the active trench;
a first upper electrode formed on an upper side with respect to the first intermediate insulating film in the active trench;
a second intermediate insulating film dividing an inside of a dummy trench into an upper part and a lower part, the dummy trench formed from the upper surface of the semiconductor substrate to the drift layer through the base layer;
a second lower electrode formed on a lower side with respect to the second intermediate insulating film in the dummy trench;
a second upper electrode formed on an upper side with respect to the second intermediate insulating film in the dummy trench;
an interlayer insulating film formed on the semiconductor substrate to cover the active trench and the dummy trench;
a gate wiring connected to the first lower electrode, the first upper electrode and the second lower electrode;
a metal film embedded in an opening formed in a stripe shape along the active trench and the dummy trench in plan view in the interlayer insulating film; and
an emitter electrode formed on the interlayer insulating film, not entering the opening, connected to the second upper electrode, and connected to the base layer and the source layer via the metal film embedded in the opening,
wherein the metal film has a higher young's modulus than that of each of the emitter electrode and the semiconductor substrate.

2. The semiconductor device according to claim 1, wherein the metal film is formed on an upper surface of the interlayer insulating film and has a higher young's modulus than that of the interlayer insulating film.

3. The semiconductor device according to claim 1, further comprising a barrier metal formed between the semiconductor substrate and the metal film in the opening and having a higher thermal expansion coefficient than that of the metal film.

4. The semiconductor device according to claim 1, wherein a first contact hole that passes through the interlayer insulating film and reaches the second upper electrode is formed, and
the emitter electrode is connected to the second upper electrode via the metal film embedded in the first contact hole.

5. The semiconductor device according to claim 1, further comprising
a gate pad formed on the interlayer insulating film, and
a resistor formed on the semiconductor substrate and covered by the interlayer insulating film,
wherein the gate wiring is formed on the interlayer insulating film,
a second contact hole and a third contact hole are formed in the interlayer insulating film,
the gate wiring is connected to one end of the resistor via the metal film embedded in the second contact hole, and
the gate pad is connected to the other end of the resistor via the metal film embedded in the third contact hole.

6. The semiconductor device according to claim 1, further comprising
a temperature sense diode formed on the semiconductor substrate and covered by the interlayer insulating film, and
an anode electrode and a cathode electrode formed on the interlayer insulating film,
wherein the temperature sense diode is a pn diode made of polysilicon,
a fourth contact hole and a fifth contact hole are formed in the interlayer insulating film,
the anode electrode is connected to one end of the temperature sense diode via the metal film embedded in the fourth contact hole, and
the cathode electrode is connected to the other end of the temperature sense diode via the metal film embedded in the fifth contact hole.

7. The semiconductor device according to claim 1, wherein the semiconductor substrate includes a main cell part and a current sense part, and
in each of the main cell part and the current sense part, the active trench and the dummy trench are formed, and the emitter electrode is connected to the base layer and the source layer via the metal film embedded in the opening.

8. The semiconductor device according to claim 1, wherein the metal film is made of tungsten.

9. The semiconductor device according to claim 1, further comprising a lower electrode formed on a lower surface of the semiconductor substrate,
wherein the emitter electrode has a tensile stress as an internal stress, and
the lower electrode has a compression stress as an internal stress.

10. The semiconductor device according to claim 1, wherein the semiconductor substrate is made of silicon.

11. The semiconductor device according to claim 1, wherein the interlayer insulating film is made of SiN.

12. The semiconductor device according to claim 1, wherein a size of the semiconductor substrate is 110 mm² or more.

13. The semiconductor device according to claim 1, wherein the semiconductor device is an IGBT or RC-IGBT.

14. A semiconductor device comprising:
a semiconductor substrate including a drift layer of a first conductivity type, a base layer of a second conductivity type formed on the drift layer, and a source layer of a first conductivity type formed on a part of the base layer;
a first intermediate insulating film dividing an inside of an active trench into an upper part and a lower part, the active trench formed from an upper surface of the semiconductor substrate to the drift layer through the base layer and the source layer;
a first lower electrode formed on a lower side with respect to the first intermediate insulating film in the active trench;
a first upper electrode formed on an upper side with respect to the first intermediate insulating film in the active trench;
a second intermediate insulating film dividing an inside of a dummy trench into an upper part and a lower part, the dummy trench formed from the upper surface of the semiconductor substrate to the drift layer through the base layer;
a second lower electrode formed on a lower side with respect to the second intermediate insulating film in the dummy trench;
a second upper electrode formed on an upper side with respect to the second intermediate insulating film in the dummy trench;
an interlayer insulating film formed on the semiconductor substrate to cover the active trench and the dummy trench;
a gate wiring connected to the first lower electrode, the first upper electrode and the second lower electrode;
an emitter electrode formed on the interlayer insulating film, connected to the second upper electrode, and connected to the base layer and the source layer via a contact hole formed in the interlayer insulating film; and
a lower electrode formed on a lower surface of the semiconductor substrate,
wherein the emitter electrode has a tensile stress as an internal stress, and
the lower electrode has a compression stress as an internal stress.

15. The semiconductor device according to claim 14, wherein the emitter electrode is made of aluminum, and
the lower electrode is made of nickel vanadium or molybdenum.

16. The semiconductor device according to claim 14, wherein the semiconductor substrate is made of silicon.

17. The semiconductor device according to claim 14, wherein the interlayer insulating film is made of SiN.

18. The semiconductor device according to claim 14, wherein a size of the semiconductor substrate is 110 mm² or more.

19. The semiconductor device according to claim 14, wherein the semiconductor device is an IGBT or RC-IGBT.
